(19) United States
(12) Patent Application Publication
(10) Pub. No.: US 2018/0019570 A1
(43) Pub. Date: Jan. 18, 2018

(54) TEMPERATURE CONTROL FOR AN IMAGING LASER

(71) Applicant: HP INDIGO B.V., Amstelveen (NL)

(72) Inventors: Elad Yaakobi, Ness Ziona (IL); Haim Vladomirski, Rehovot (IL); Oron Ambar, Ness Ziona (IL)

(73) Assignee: HP INDIGO B.V., Amstelveen (NL)

(21) Appl. No.: 15/545,943

(22) PCT Filed: Apr. 1, 2015
(86) PCT No.: PCT/EP2015/000710

§ 371 Date: Jul. 24, 2017

(51) Int. Cl. H01S 5/068; H01S 5/024; G03G 21/20; G03G 15/043; H01S 5/40; G03G 15/04

(52) U.S. Cl. CPC H01S 5/06804; H01S 5/4025; H01S 5/06812; G03G 15/04072; G03G 21/20; G03G 15/043; H01S 5/02415

(57) ABSTRACT

In one example, an imaging system (10) for a laser printer includes: an imaging laser (26) in which, within a range of drive currents, a threshold current of the laser varies with temperature and an efficiency of the laser does not vary with temperature; a power sensor (20) to measure an output power of the laser at a drive current within the range of drive currents; and a temperature control device (32) to change the temperature of the laser based on an output power measured by the power sensor.

### BACKGROUND

In some electrophotographic printers, an electrostatic charge pattern representing a printed image is formed on a photoconductor by scanning an array of laser beams across the photoconductor. Electrophotographic printers that use scanning laser beams to image the photoconductor are commonly referred to as “laser” printers. The laser beams are modulated to form the desired charge pattern on the photoconductor. This so-called “latent” image is developed into a visible image by applying a thin layer of toner to the patterned photoconductor. Charged particles in the toner adhere to the charge pattern on the photoconductor. The toner image is then transferred from the photoconductor to the paper or other print substrate, directly or indirectly through an intermediate transfer member. Some laser printers use dry toner in dry electrophotographic (DEP) processes and some use liquid toner in liquid electrophotographic (LEP) processes. (Liquid toner is sometimes commonly referred to as ink, LEP ink or Electrolnk®.)

### DRAWINGS

FIGS. 1 and 2 illustrate one example of a photoimaging system for a laser printer. FIG. 1 shows the system during an imaging sequence when image data is scanned to a photoconductor. FIG. 2 shows the system during an imaging sequence executing a temperature control function for an individual laser.

FIG. 3 is a block diagram illustrating one example of a temperature control system such as might be implemented in the imaging system shown in FIGS. 1 and 2.

FIG. 4 is a block diagram illustrating one example of a temperature controller in the control system shown in FIG. 3.

FIGS. 5 and 8 are flow diagrams illustrating examples of a temperature control process.

FIG. 6 illustrates one example of a power curve for an imaging laser.

FIG. 7 illustrates a power curve for an imaging laser over a range of drive currents and temperatures in which the slope the power curve is constant.

The same part numbers designate the same or similar parts throughout the figures. The figures are not to scale.

### DESCRIPTION

The output power of a laser, and thus the optical power of its beam, varies with the temperature of the laser. For example, the output power of the laser may decrease as the laser becomes warmer. It is usually desirable, therefore, to maintain printer imaging lasers at a constant temperature to help reduce unwanted variations in the optical power of the modulated laser beams that image the photoconductor. Currently, the temperature of lasers used in the imaging array for some laser printers is controlled based on signals from a thermocouple, thermistor or other temperature sensor. These types of direct temperature sensors may not always reliably detect rapid changes in temperature. In addition, temperature sensors measuring the average temperature of the laser array as a whole may be inadequate to control rapid temperature changes of individual lasers, particularly for laser arrays formed in a monolithic integrated circuit device.

A new technique has been developed to improve temperature control for imaging lasers for more consistent output power and, thus, better print quality. In one example, a laser's threshold current is used as a proxy for temperature to enable faster and more accurate temperature measurement and control. In this example, the output power of each laser in the imaging array is measured individually with a power sensor, for instance during idle periods between scans to the photoconductor. The threshold current is determined from the measured output power, based on the slope of the laser's power curve, and then compared to a target threshold current corresponding to the desired laser temperature. If the threshold current is different from the target, then the thermoelectric cooler or other temperature control device is signaled to increase or decrease cooling depending on whether the threshold current is more or less than the target.

In another example, a relationship between drive current and output power for each laser is established for a range of drive currents in which the threshold current of the laser varies with temperature but the efficiency of the laser does not vary with temperature (i.e., the slope of the power curve is constant). Periodically during an imaging sequence, each of the lasers in the imaging array is driven to emit a beam that is directed to a power sensor. The power sensor measures the output power of the laser. The temperature of the laser can then be changed based on the measured output power, for example by using threshold current as a proxy for temperature as described above.

The temperature control sequences in these examples may be performed for each laser individually to enable faster temperature control compared to current techniques. In addition, the sequences may be repeated periodically and iteratively for each laser in the array at any drive current to help maintain the desired temperature throughout an imaging sequence.

These and other examples shown in the figures and described in detail below illustrate but do not limit the scope of the patent. Therefore, this Description should not be construed to limit the scope of the patent, which is defined in the Claims following the Description.

As used in this document, a “laser” means a device that produces a beam of coherent light; and “light” means electromagnetic radiation of any wavelength.

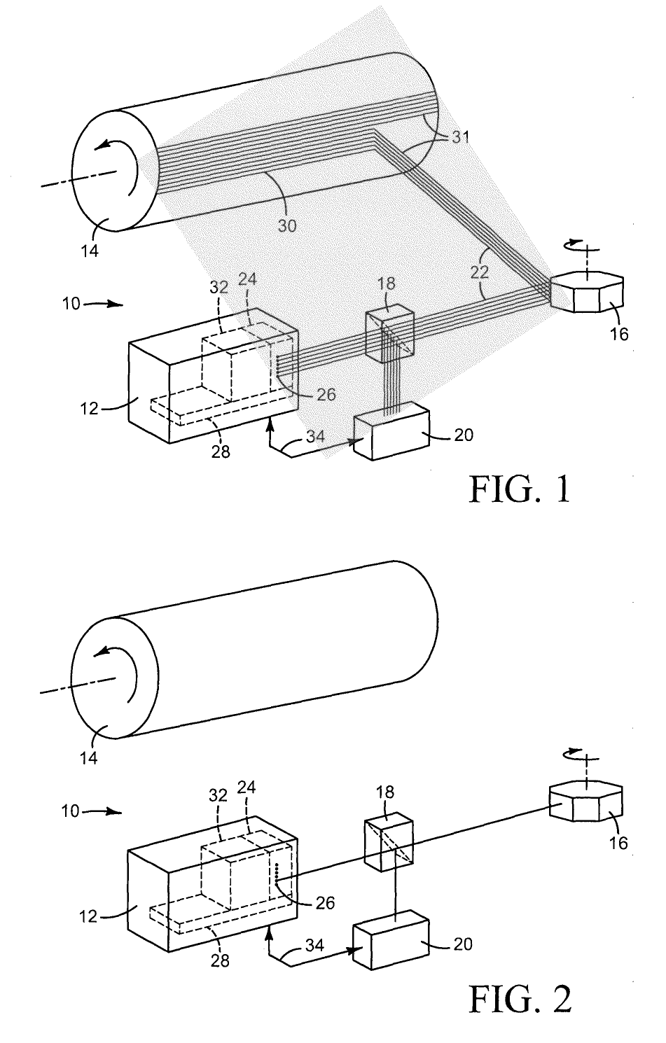

FIGS. 1 and 2 illustrate one example of a photoimaging system 10 for a laser printer. FIG. 1 shows system 10 during imaging when image data is scanned to the photconductor. FIG. 2 shows system 10 executing a temperature control function for an individual laser. Referring to FIGS. 1 and 2, system 10 includes an imaging unit 12, a photoconductor 14, a polygonal mirror 16, a beam splitter 18, and a power sensor 20. Imaging unit 12 emits laser beams 22 from a laser assembly 24 that includes an array of multiple lasers 26. Laser assembly 24 may be implemented, for example, as a monolithic integrated circuit with laser diodes 26.

Beams 22 are directed toward a spinning polygonal mirror 16 that scans the light beams across the rotating photoconductor 14. A controller 28 receives and processes image data to modulate the emission of laser beams 22 and to control mirror 16 and other components of imaging system 12 to scan beams 22 on to photoconductor 14 in the desired charge pattern 30. Controller 28 in FIGS. 1 and 2 represents generally the programming, processor and associated memory, and the electronic circuitry and components needed to control the operative elements of imaging system 10. Controller 28 may be implemented as part of an integrated printer controller or as a discrete imaging system controller that coordinates with other printer control functions. Controller 28 may include multiple controller and microcontroller components such as, for example, general purpose processors, microprocessors, and application specific integrated circuits (ASICs).

As shown in FIG. 1, a small portion of laser beams 22 are directed to power sensor 20 as they pass through beam splitter 18. As shown in FIG. 2 and described in detail below, during temperature control, lasers 26 are energized individually to send part of a single beam 22 to power sensor 20. Temperature control lasing may be performed, for example, during idle periods between scans to photoconductor 14.

In the example shown in FIG. 1, six parallel beams are emitted from laser assembly 24 and scanned simultaneously in swaths 31 across photoconductor 14. The overall result is that the modulated laser beams 22 form a latent image 30 on photoconductor 14 in successive swaths 31 each with six lines of pixels. Two swaths 31 are shown in FIG. 1. A single printed page may include many swaths 31 and a single print job may include many pages. Accordingly, FIG. 1 illustrates just one point in time during an imaging operation. An imaging system 12 usually will include lenses and other components not shown in FIG. 1 to shape and direct the laser beams. Also, while six parallel beams 22 are shown, more or fewer beams and/or with different orientations may be used.

Referring again to both FIGS. 1 and 2, imaging unit 12 also includes a temperature control device 32 to control the temperature of lasers 26. While it is expected that temperature control device 32 usually will be implemented as a thermoelectric cooler, other suitable implementations for a temperature control device 32 are possible. The temperature of individual lasers 26 may be monitored dynamically through a feedback circuit 34 between power sensor 20 and temperature control device 32, as described in more detail below. Temperatures different from a target temperature may be corrected by adjusting temperature control device 32.

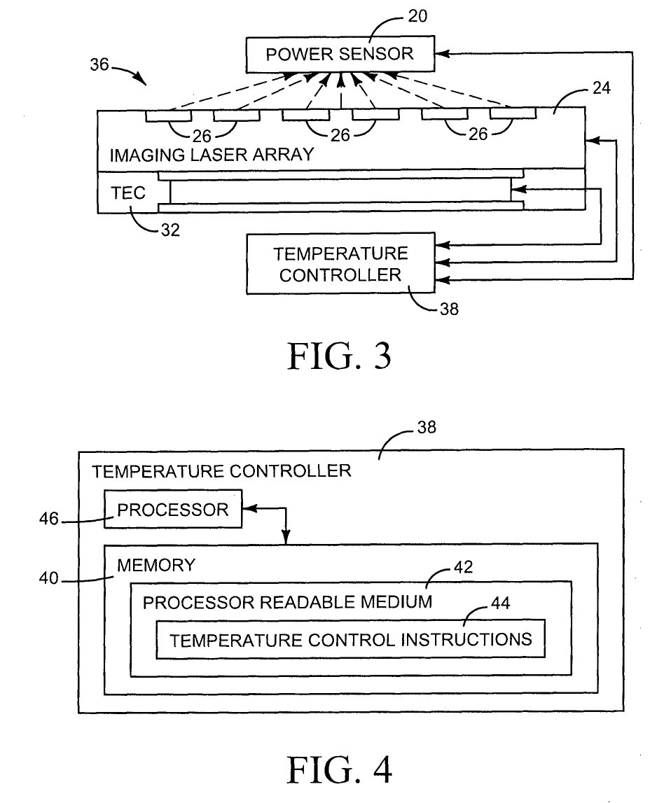

FIG. 3 is a block diagram illustrating one example of a temperature control system 36 such as might be implemented in imaging system 10 shown in FIGS. 1 and 2. FIG. 4 is a block diagram illustrating one example of the temperature controller shown in FIG. 3. Referring first to FIG. 3, temperature control system 36 includes a power sensor 20, a thermoelectric cooler (TEC) 32, a feedback circuit 34, and a temperature controller 38. Thermoelectric cooler 32 in FIG. 3 may be implemented, for example, as a single cooler 32 with cooling current circuits to cool each laser 26 individually or collectively with other lasers in the array, or as multiple coolers 32 each configured to cool a single laser 26.

Also, while it is expected that a temperature controller 38 usually will be implemented as an integral part of imaging system controller 28 shown in FIGS. 1 and 2, it may be desirable in some applications to implement temperature controller 38 as a discrete component. Controller 38 represents generally the programming, processor and associated memory, and the electronic circuitry and components needed to control the operative elements of temperature control system 36. Controller 38 may include controller and microcontroller components such as, for example, a general purpose processor, microprocessor, and/or application specific integrated circuit (ASIC).

In the example shown in FIG. 4, controller 38 includes a memory 40 having a processor readable medium 42 with temperature control instructions 44 and a processor 46 to read and execute instructions 44. A processor readable medium 42 is any non-transitory tangible medium that can embody, contain, store, or maintain instructions for use by a processor 46. Processor readable media include, for example, electronic, magnetic, optical, electromagnetic, or semiconductor media. More specific examples of suitable processor readable media include a hard drive, a random access memory (RAM), a read-only memory (ROM), and memory cards and sticks. Temperature control instructions 44 may be embodied, for example, in software, firmware, and/or hardware. Memory 40 and processor 42 are not necessarily discrete components in controller 38 but may be implemented, for example, in an application specific integrated circuit (ASIC).

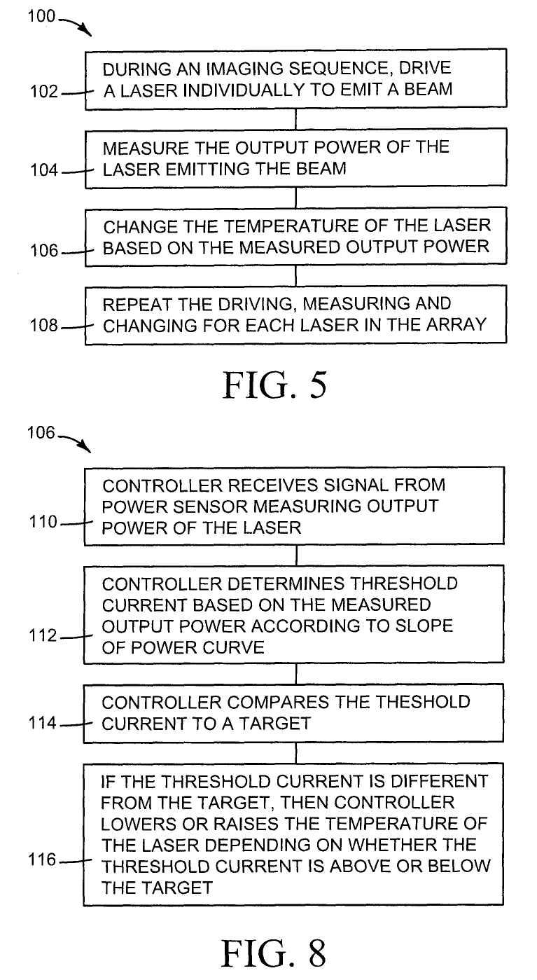

FIG. 5 illustrates one example of a temperature control process 100 such as might be implemented with instructions 44 on controller 38 in FIGS. 3 and 4. (Part numbers from FIGS. 1-4 are used in the following description.) Referring to FIG. 5, during an imaging sequence in which a latent image 30 is being formed on photoconductor 14, a laser 26 is driven individually to emit beam 22 that is directed to sensor 20 as shown in FIG. 2 (block 102). As noted above, temperature control lasing in block 102 may be performed, for example, during idle periods between imaging scans to photoconductor 14. The output power of the laser 26 is measured by sensor 20 (block 104) and the temperature of laser 26 changed by cooler 32 based on the measured output power (block 106). The temperature of laser 26 may be changed individually or with other lasers in the array. The driving, measuring and changing at blocks 102-106 are repeated for each laser 26 in array 24 (block 108). Also, the driving, measuring and changing at blocks 102-106 may be repeated iteratively for an individual laser 26 as desired, for example until the target temperature is reached or until a set number of iterations are completed.

Temperature control process 100 may be executed while lasers 26 are otherwise idle during an imaging sequence. Idle periods may occur normally in an imaging sequence, for example at the start of a scan or between scans of swaths 31. Idle periods may be added to an imaging sequence specifically for temperature control. Also, the driving, measuring and changing may be performed during a single idle period for all of the lasers in the array or for only some of the lasers in the array.

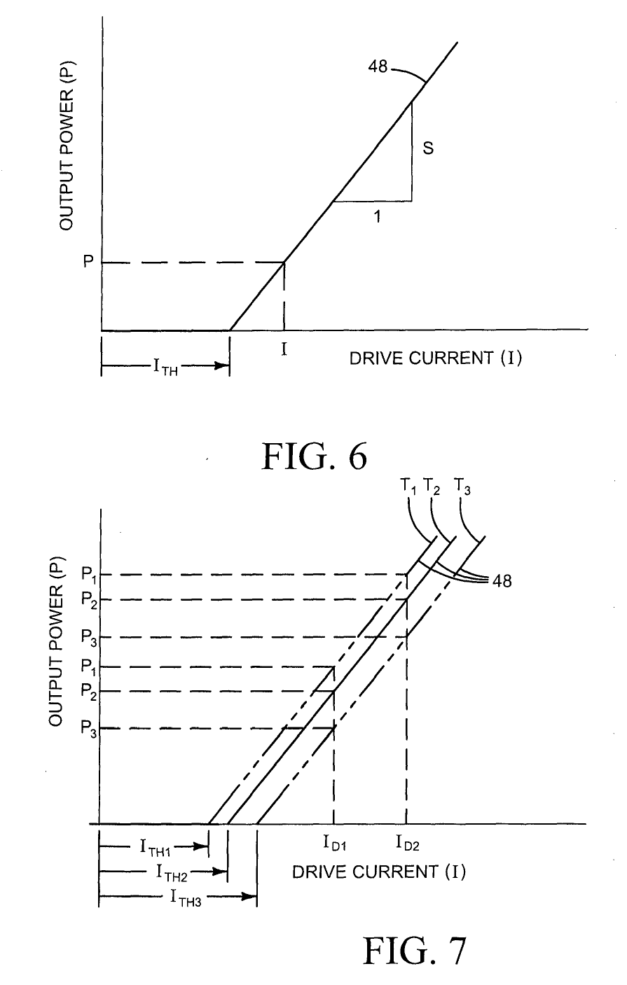

FIG. 6 illustrates one example of a power curve 48 for an imaging laser 26 in array 24. While it is expected that each laser 26 in array 24 usually will have the same power curve 48, individual lasers 26 or groups of lasers 26 in the array may have different power curves 48. Referring to FIG. 6, the output power P of a laser is a function of the drive current I. This function is represented by power curve 48 which, in this example, is a straight line. The slope S of line 48 represents the efficiency of the laser, and is sometimes referred to as “slope efficiency.” The threshold current I_{TH} is the minimum current needed for lasing. That is to say, the power output of the laser is 0 at drive currents less than ITH. The threshold current I_{TH} for a laser may be determined based on the slope S of power curve 48 by measuring the output power P at a known drive current I.

FIG. 7 illustrates power curves 48 for an imaging laser 26 in imaging unit 12 in FIG. 1 over a range of drive currents I and temperatures T in which the slope S of curve 48 is constant. In some laser printers, the desired output power for properly imaging photoconductor 14 with modulated laser beams 22 can be achieved within a range of drive currents in which the slope of the power curve is constant, provided the temperature of each laser is controlled to stay within this range. Quicker reaction times that may be realized by implementing examples of the new temperature control system help minimize temperature fluctuations outside the desired range of laser operating temperatures.

As shown in FIG. 7, the threshold current I_{TH} and thus the output power P of a laser varies with temperature T. Accordingly, the temperature of a laser 26 at any drive current I applied during an imaging sequence can be estimated by measuring output power at sensor 20 and determining the corresponding threshold current at controller 38 using the constant slope S of power curve 48. If the determined threshold current is different from the threshold current corresponding to the target temperature, current flow through thermoelectric cooler 32 may be adjusted to correct the temperature of the laser. The control sequence may be repeated iteratively for each laser in the array at any drive current to maintain the target temperature.

FIG. 7 illustrates one example for threshold currents I_{TH1}-I_{TH3} and output powers P₁-P₃ corresponding to laser temperatures T₁-T₃ for a laser 26 with power curve 48. The power curve 48 and target temperature for each laser 26 may be determined empirically, for example, during periodic calibration. For commercial digital laser printing presses, it is common to calibrate the laser array each time the press is started. During calibration, each laser 26 may be driven to the desired output power for properly imaging photoconductor 14 and the temperature of the lasers measured directly to establish a target temperature. The “target temperature” may be a single temperature or a range of temperatures. The temperature of each laser 26 may be measured directly or an average temperature of the array 24 may be used to establish the target temperature. Also during calibration, the power curve and/or the range of drive currents and operating temperatures (where the slope of the power curve is constant) for each laser may be established or re-established, if desired, by measuring output power at different drive currents and temperatures.

Still referring FIG. 7, a power curve 48 has been established with a constant slope for a range of drive currents including I_{D1} and I_{D2} and for a range of temperatures including T₁-T₃. In this example, T₂ is established as the target temperature for each laser 26. Power curve 48 corresponding to target temperature T₂ is depicted with a solid line in FIG. 7. Power curves 48 corresponding to aberrant temperatures T₁, and T₃, are depicted in phantom lines in FIG. 7. For temperature control during an imaging sequence, each laser 26 is driven at current I_{D1} to emit a beam 22 that is directed to power sensor 20. Power sensor 20 may be any suitable device for measuring the output power of a laser 26 including, for example, an optical sensor, a thermopile sensor or a pyroelectric sensor. Temperature controller 38 receives a signal from sensor 20 measuring the output power of laser 26. Controller 38 determines a threshold current I_{TH} based on the measured output power according to the slope S of curve 48.

If the determined threshold current matches the threshold current I_{TH2} corresponding to the target temperature T₂, then no change is made to the temperature of the laser. This condition is indicated by threshold current I_{TH2} and measured output power P₂ for drive current I_{D1} in FIG. 7. If the determined threshold current is less than the threshold current I_{TH2} corresponding to the target temperature T₂, then the temperature of the laser is raised, for example by reducing cooling current flow in thermoelectric cooler 32. This condition is indicated by threshold current I_{TH1} and measured output power P₁ for drive current I_{D1} in FIG. 7. If the determined threshold current is greater than the threshold current I_{TH2} corresponding to the target temperature T₂, then the temperature of the laser is lowered, for example by increasing cooling current flow in thermoelectric cooler 32. This condition is indicated by threshold current I_{TH3} and measured output power P₃ for drive current I_{D1} in FIG. 7.

A second example is shown for a drive current I_{D2} in FIG. 7. Temperature control in FIG. 7 may be executed at any drive current within the range of constant slopes for power curve 48.

Referring now to the flow diagram of FIG. 8, which illustrates one example for changing the temperature of an individual laser at block 106 in FIG. 5, controller 38 receives a signal from power sensor 20 measuring the output power of a laser 26 (block 110) and then determines the threshold current based on the measured output power according to the slope of power curve 48 (block 112), for example as described above with reference to FIG. 7. Controller 38 compares the threshold current determined at block 112 to a target threshold current (block 114). If the threshold current is different from the target, controller 38 lowers or raises the temperature of the laser 26 depending on whether the threshold is above or below the target, for example by adjusting the cooling current flow in a thermoelectric cooler 32.

Although the target temperature T₂ and thus the target threshold current I_{TH2} are single values in FIG. 7, the target may be range of values T and I_{TH}. Also, while a temperature control process 100 in FIGS. 5 and 8 may proceed iteratively for an individual laser until reaching the target using a static increment of change, it may be desirable in some implementations to adjust the cooling dynamically, proportional to the size of the difference between the determined value and the target. For example, at block 114 in FIG. 8 controller 38 compares the threshold current to the target and determines the difference, if any, in the two values. Then, at block 116 controller 38 changes the temperature of the laser in an amount proportional to the difference, for example by adjusting the cooling current flow in thermoelectric cooler 32 in the desired amount. A temperature control process 100 may proceed iteratively for an individual laser 26 as desired, for example until the target is reached or until a set number of iterations are completed.

As noted at the beginning of this Description, the examples shown in the figures and described above illustrate but do not limit the scope of the patent. Other examples are possible. Therefore, the foregoing description should not be construed to limit the scope of the patent, which is defined in the following Claims.

“A” and “an” as used in the Claims means one or more.

What is claimed is:

1. An imaging system for a laser printer, comprising:
an imaging laser in which, within a range of drive currents, a threshold current of the laser varies with temperature and an efficiency of the laser does not vary with temperature;
a power sensor to measure an output power of the laser at a drive current within the range of drive currents; and
a temperature control device to change the temperature of the laser based on an output power measured by the power sensor.

2. The system of claim 1, where:
the imaging laser comprises multiple imaging lasers arrayed to simultaneously image a photoconductor, each laser in the array having, within a range of drive currents, a threshold current that varies with temperature and an efficiency that does not vary with temperature;
the power sensor is to measure an output power of each of the lasers individually at a drive current within the range of drive currents; and
the temperature control device is to change the temperature of the array or of each of the lasers individually based on an output power measured by the power sensor.

3. The system of claim 2, comprising a controller to, during an imaging sequence:
drive each laser individually to emit a beam;
receive a signal from the power sensor measuring an output power of the laser emitting the beam;
determine a threshold current for the laser based on the measured output power;
compare the threshold current to a target; and
if the threshold current is different from the target, cause the temperature control device to change the temperature of the laser.

4. An imaging system for a laser printer, comprising:
an array of multiple lasers to image a photoconductor;
a power sensor to sense an output power of each of the lasers individually;
a thermoelectric cooler to cool the lasers; and
a temperature controller having a processor and a tangible non-transitory processor readable medium with instructions thereon when executed by the processor cause the controller to:
receive a signal from the power sensor measuring an output power of one of the lasers in the array;
determine a threshold current for the laser based on the measured output power;
compare the threshold current to a target;
if the threshold current is greater than the target, then cause the thermoelectric cooler to increase cooling current to the laser;
if the threshold current is less than the target, then cause the thermoelectric cooler to decrease cooling current to the laser; and
repeat the receiving, determining, and comparing for each laser in the array.

5. The imaging system of claim 4, where the thermoelectric cooler is to cool each of the lasers individually.

6. The imaging system of claim 4, where the thermoelectric cooler is to cool each laser together with other lasers as part of the array.

7. The imaging system of claim 4, where the instructions include instructions that when executed by the processor cause the controller to establish a relationship between drive current and output power for each laser for a range of drive currents in which the threshold current of the laser varies with temperature and an efficiency of the laser does not vary with temperature.

8. The imaging system of claim 4, where the instructions include instructions that when executed by the processor cause the controller to repeat the receiving, determining, and comparing for each laser periodically during an imaging sequence when the laser is otherwise idle.

9. The imaging system of claim 4, where the power sensor is a single power sensor is to sense the output power of each of the lasers in the array and the lasers are arrayed together in a monolithic integrated circuit device.

10. A process to control the temperature of an imaging laser in an array of multiple imaging lasers, comprising:
during an imaging sequence, driving one of the lasers individually to emit a beam;
measuring the output power of the laser emitting the beam;
changing the temperature of the laser based on the measured output power; and
repeating the driving, measuring and changing for each laser in the array.

11. The process of claim 10, where the changing comprises:
determining a threshold current of the laser based on the measure output power according to a slope of a power curve for the laser;
comparing the threshold current to a target; and
if the threshold current is different from the target, lowering or raising the temperature of the laser depending on whether the threshold current is above or below the target.

12. The process of claim 11, where:
the imaging sequence includes scanning beams from multiple lasers in the array in successive swaths across a photoconductor; and
the driving includes driving each one of the lasers individually during a period before or between scanning swaths across the photoconductor.

13. The process of claim 12, where each of the lasers is driven at a drive current within a range of drive currents in which a threshold current of the laser varies with temperature and an efficiency that does not vary with temperature.

14. A tangible non-transitory processor readable medium having instructions thereon that when executed cause an imaging device to control a temperature of each imaging laser in the device using laser threshold current as a proxy for temperature.

15. The processor readable medium of claim 14, where the instructions to control the temperature using laser threshold current include instructions that when executed cause the imaging device to:
measure the output power of each laser;
determine a threshold current for the laser from the measured output power, based on the slope of the laser's power curve; and then
compare the threshold current to a target.
